(19) United States
(12) Patent Application Publication
(10) Pub. No.: US 2023/0408566 A1
(43) Pub. Date: Dec. 21, 2023

(54) 3D REAL-TIME ANTENNA CHARACTERIZATION

(71) Applicant: TECHNISCHE UNIVERSITEIT DELFT, Delft (NL)

(72) Inventors: Marco SPIRITO, Delft (NL); Ferdinand Alexander MUSTERS, Delft (NL); Earl William MC CUNE JR., Delft (NL)

(73) Assignee: TECHNISCHE UNIVERSITEIT DELFT, Delft (NL)

(21) Appl. No.: 18/253,049

(22) PCT Filed: Nov. 18, 2021
(86) PCT No.: PCT/EP2021/082198

§ 371 Date: May 16, 2023

(30) Foreign Application Priority Data
Nov. 19, 2020 (NL) 2026930

(51) Int. Cl. G01R 29/10; G01R 29/08

(52) U.S. Cl. CPC G01R 29/105; G01R 29/0821

(57) ABSTRACT

An assembly for characterizing a device under test (DUT) (2), comprising a dome (5) forming a test chamber. The assembly further comprises a plurality of sampling units (4), wherein during characterization of the DUT (2) the plurality of sampling units (4) are static with respect to the DUT (2) and the dome (5), and spatially distributed over the dome (5) in a far-field range of the DUT (2). The plurality of sampling units (4) are configured to receive a signal inside the test chamber, and transmit an output signal based on the received signal for further analysis. In a further aspect, a method for characterizing a DUT (2) is also provided.

### FIELD OF THE INVENTION

The present invention relates to an assembly for characterizing a device under test, the assembly comprising a plurality of sampling units. The invention further relates to a method for characterizing a device under test.

### BACKGROUND ART

US patent application US 2018/006745 discloses a system for characterizing a device under test including an integrated antenna array. The system includes an optical subsystem having first and second focal planes, where the integrated antenna array is positioned substantially on the first focal plane of the optical subsystem. The system includes a measurement array having one or more array elements positioned substantially on the second focal plane of the optical subsystem, the measurement array being configured to receive signals transmitted from the integrated antenna array via the optical subsystem. Even further, the system includes a transceiver and selectively connected to the measurement array through a switch.

US patent application US 2018/076907 discloses a measuring system for determining a beamforming quality of an antenna array signal of an antenna array of a device under test. The measuring system comprises a measuring device configured to receive an antenna array signal, and to measure the antenna array signal. The measuring system further comprises a positioning unit configured to position the device under test in successive predefined orientations. The measuring device is configured to receive and measure the antenna array signal successively in each of the predefined orientations.

### SUMMARY OF THE INVENTION

The present invention seeks to provide an assembly for characterizing a device under test with a relatively short characterization time.

According to the present invention, an assembly as defined above is provided, further comprising a dome forming a test chamber, wherein during a characterization of the DUT the plurality of sampling units are static with respect to the DUT and the dome, and spatially distributed over the dome in a far-field range of the DUT, and configured to receive a signal inside the test chamber, and transmit an output signal based on the received signal for further analysis.

These features have an advantage that they may allow for a relatively quick characterization of a DUT.

### SHORT DESCRIPTION OF DRAWINGS

The present invention will be discussed in more detail below, with reference to the drawings, in which

FIG. 1 shows a schematic view of an assembly, according to an embodiment of the present invention;

FIG. 2A shows a schematic view of a part of the assembly, according to another embodiment of the present invention;

FIG. 2B shows a schematic view of a part of the assembly, according to a further embodiment of the present invention;

FIG. 2C shows a schematic view of a part of the assembly, according to an even further embodiment of the present invention;

FIG. 3A shows a schematic view of the plurality of sampling units spatially distributed over the dome, according to a first ‘pattern’ embodiment of the present invention;

FIG. 3B shows a schematic view of the plurality of sampling units spatially distributed over the dome, according a second ‘pattern’ embodiment of the present invention;

FIG. 3C shows a schematic view of the plurality of sampling units spatially distributed over the dome, according a third ‘pattern’ embodiment of the present invention;

FIG. 4A shows a schematic view of the dome, according to an exemplary embodiment of the present invention;

FIG. 4B shows a schematic view of part of the dome shown in FIG. 4A, according to a further exemplary embodiment of the present invention, and

FIG. 5 shows a flow diagram of a method for characterizing a device under test, according to an embodiment of the present invention.

### DESCRIPTION OF EMBODIMENTS

Certain exemplary embodiments will be described in greater detail, with reference to the accompanying drawings. The matters disclosed in the description, such as detailed construction and elements, are provided to assist in a comprehensive understanding of the exemplary embodiments. Accordingly, it is apparent that the exemplary embodiments can be carried out without those specifically defined matters. Also, well-known operations or structures are not described in detail, since they would obscure the description with unnecessary detail. The drawings are diagrammatic and may not be drawn to scale. Throughout the drawings, similar items may be marked with the same reference numerals.

Antenna characterization is a step in the development of basic radiating elements, as well as advanced antenna array systems. Typically, the characterization of antennas, or antenna systems, is performed in an anechoic chamber, in which a probe antenna mechanically scans over a number of specific surfaces, e.g. a plane, cylinder or sphere, over the antenna under test (AUT). Alternatively, the AUT may mechanically scan over the specific surfaces, and the probe antenna is kept in a fixed position.

However, a current bottleneck in this characterization approach may be the time used to acquire the field intensity over a sufficient number of measurement points in order to accurately characterize the AUT, for example, accurately reconstruct the radiation pattern of the AUT. Although multiple probe antennas can be employed in order to reduce the characterization time, partial mechanical and/or electronic scanning is still present in state-of-the art system implementations.

Furthermore, electronic switching is also present in existing characterization approaches. To elaborate, state-of-the-art systems often have one or more probe antennas to transfer high frequency signals from an AUT to a switching unit, e.g. a multiplexer, where after, it is measured in a single high performance stimulus acquisition unit, e.g. a vector network analyzer and/or a spectrum analyzer, for further processing, for example, signal digitization. Not only does this further increase the characterization time, but such electronic instrumentation is also expensive, driving up the cost of antenna characterization. In addition, the cabling to transfer the high frequency signals to such electronic instrumentation may have non-negligible losses, which further reduces the (already weak) signals from the AUT, impacting the dynamic range of the setup.

At present, the characterization time of state-of-the-art systems is in the range between thirty minutes, to several hours. In particular, for the characterization of mm-wave modules for communications, large measurement times may be involved owing to the multiple antenna configurations that can be synthesized by the mm-wave antenna arrays i.e. beam scanning systems. This limitation might provide a real bottleneck for the cost reduction of the access points operating in the FR2 (26-42 GHz) band.

Similarly, although performance prediction methods, e.g. internal calibration schemes or modelling of the front-end behavior, can be employed to speed up the characterization time, this is still carried out without physical validation, i.e. production line testing and validation, which may lead to inaccurate characterization and lower performance.

Therefore, there is a need to overcome these bottlenecks, and provide an approach whereby the characterization time is significantly reduced to e.g. a matter of seconds, and of low costs. This would increase the production line of antennas or antenna systems, allowing increased volume production testing, and, hence, a decreasing cost per unit. Moreover, in research and development practices, the characterization time being significantly reduced may also allow the measurement of an AUT in multiple configurations within a short time span, thereby increasing the efficiency of antenna characterization.

Other advantages of the removal of certain moving parts may include reduced manufacturing cost, reduced maintenance, improved reliability, and/or improved durability of a test assembly.

The present invention embodiments provide an assembly for characterizing a device under test (DUT), whereby the operation principle is based on a plurality of static sampling points. In certain embodiments, no mechanical scanning is involved. This allows high speed, accurate characterization of a DUT, which can be performed in e.g. less than a second, significantly reducing the time and costs involved. In a further aspect, a method for characterizing a DUT is also provided. Herein, a device under test may comprise an antenna (system) under test.

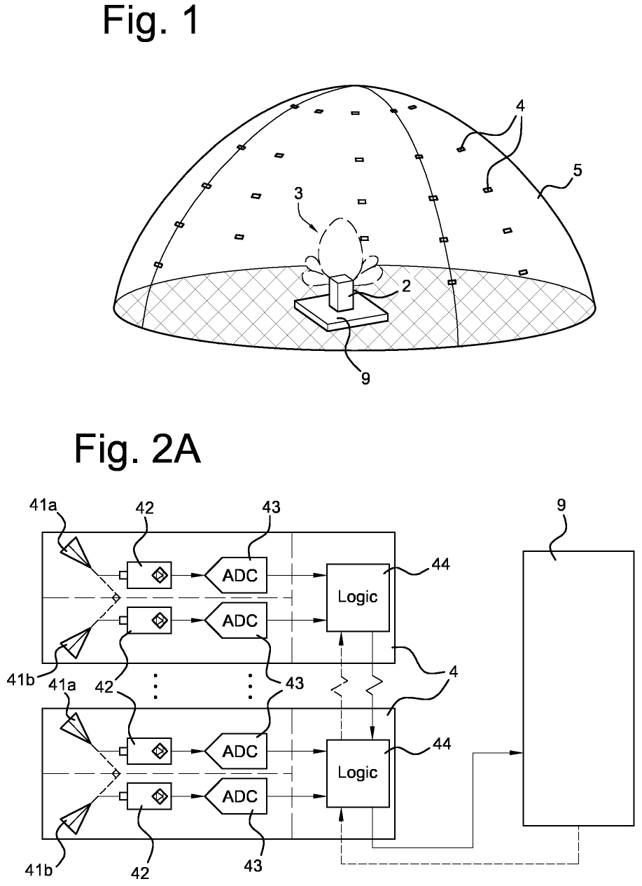

FIG. 1 shows a schematic view of an assembly for characterizing a DUT 2, according to an embodiment of the present invention. In this embodiment, the assembly comprises a dome 5 forming a test chamber. The dome 5 may comprise any geometric type of dome, e.g. hemispherical, pointed, catenary, faceted, cloister, assuming the operational principle of the present invention embodiments described herein may be carried out.

For example, the dome 5 may be a spherical cap or spherical dome. As another example, the dome 5 may be a spheroidal dome, which may be obtained by sectioning off a portion of a spheroid so that the resulting dome is circularly symmetric. Likewise, the dome 5 may be an ellipsoidal dome, which may be derived from the ellipsoid.

In an embodiment, the dome 5 forms an open or closed test chamber. When the dome 5 forms an open test chamber, the DUT 2 (to be characterized) may be placed within the dome 5, such that is it fully ‘exposed’ to an external environment. In this regard, the dome 5 may comprise a ‘skeleton’ forming the physical, structural framework, thereby forming the open test chamber therein.

Such an open test chamber may allow quick and easy construction of the dome 5, where, for example, the dome 5 may be placed in e.g. an external room or external setup for characterization of a DUT 2 without the need to e.g. place a cover on the structural framework of the dome 5.

When the dome 5 forms a closed test chamber, as shown in the exemplary embodiment shown in FIG. 1, the closed test chamber may comprise e.g. panels to cover at least a part of the dome 5. It is noted that the dome 5 may be constructed such that e.g. only panels are present, wherein the panels are arranged such that it forms the (closed) dome 5. Alternatively, the panels may be e.g. placed on or stapled onto the physical, structural framework already forming the dome 5.

From this perspective, for a closed test chamber, the dome 5 comprises an outer surface and an inner surface, wherein the outer surface of the dome 5 is ‘exposed’ to the external environment, and the inner surface may form the interior wall of the closed test chamber. In this respect, as shown in FIG. 1, the DUT 2 (to be characterized) may be placed within the dome 5, such that the DUT 2 is at least partly isolated and separated, via the dome 5, from the external environment, thereby forming the closed test chamber therein.

It should be pointed out that, for a closed test chamber, the use of panels represent a non-limiting implementation, and other materials, e.g. a metallic grid, strong PVC, fabric or woven polyester, may be used.

The DUT 2 may comprise any (manufactured) product, equipment or unit undergoing testing, as part of e.g. ongoing functional testing and/or calibration tests. The DUT 2 may comprise passive components. For example, there are no electronics (e.g. amplifiers) in the DUT 2, wherein the DUT 2 may be connected to other instrumentation as to generate a signal. Alternatively, the DUT 2 may comprise passive and active components, i.e. the DUT 2 may generate its own signal without being connected to any other instrumentation. In certain embodiments, the DUT 2 comprises at least one antenna, or an antenna system. For illustration purposes, an example of an exemplary radiation pattern 3, as generated by a DUT 2, is shown in FIG. 1.

In the embodiment shown in FIG. 1, the assembly further comprises a plurality of sampling units 4, wherein during characterization of the DUT 2 the plurality of sampling units 4 are static with respect to the DUT 2 and the dome 5, and spatially distributed over the dome 5. As shown in FIG. 1, the plurality of sampling units 4 are statically mounted on the dome 5 and arranged to be spread across the dome 5, wherein each of the plurality of sampling units 4 may be sufficiently distanced from one another.

Furthermore, in FIG. 1, it is shown that the plurality of sampling units 4 may be spatially distributed over the dome 5 such that the plurality of sampling units 4 encompasses e.g. the DUT 2 placed within the dome 5. In this context, the plurality of sampling units 4 may be arranged to be spatially distributed to form the shape of the dome 5.

For a dome 5 forming an open test chamber, the plurality of sampling units 4 may be statically mounted on e.g. the structural framework of the dome 5. For a dome 5 forming a closed test chamber, the plurality of sampling units 4 may be statically mounted on e.g. the panels of the dome 5 or e.g. the structural framework of the dome 5.

In certain embodiments, the plurality of sampling units 4 are separate, physical elements of the assembly that may be attached and detached from the dome 5, i.e. the placement and positions of the plurality of sampling units 4 on the dome 5 may be not permanent, and may be changeable according to the requested characterization of the DUT 2.

To elaborate, each of the plurality of sampling units 4 is attached to a certain location on the dome 5, and does not move from its respective location during the characterization of the DUT 2 for e.g. a specific duration of time. Thereafter, each of the plurality of sampling units 4 may be detached from its respective location and moved to a different location on the dome 5, as requested and desired by a user, thereby providing good convenience for the user.

Moreover, in the embodiment shown in FIG. 1, the plurality of sampling units 4 are positioned in a far-field range of the DUT 2. As known to the skilled person, in the far-field range of a DUT (also known as the radiative or Fresnel range), the radiated power may decrease according to the inverse square law, and the radiated power in the far-field range may represent e.g. the radiation pattern of a DUT. Thus, in relation to the present invention embodiments as described herein, the characterization of the DUT 2 may be performed in the far-field range of the DUT 2.

Further, in this embodiment, the plurality of sampling units 4 are configured to receive a signal inside the test chamber, and transmit an output signal based on the received signal for further analysis. In other wording, each of the plurality of sampling units 4 locally sample the signal, e.g. a propagating, over-the-air (OTA) or wireless signal of high frequency, received from a DUT 2 placed within the dome 5, and send an output signal for further analysis to obtain characterization information about the DUT 2. As a non-limiting example, the plurality of sampling units 4 may locally acquire two orthogonal field polarizations (for example the E-plane and H-plane) to determine the total field (i.e. an electromagnetic wave signal) at various orientation angles.

From this standpoint, the features of the plurality of sampling units 4 being statically mounted on the dome 5, and being configured to receive a signal from inside the test chamber and transmit an output signal, obviates the need for any mechanical scanning; the DUT 2, or the plurality of sampling units 4, do not need to mechanically scan over a large number of specific surfaces as to acquire a sufficient number of measurement points.

In more general wording, the present invention embodiments, as described herein, relate to an assembly for characterizing a DUT 2, comprising a dome 5 forming a test chamber, and a plurality of sampling units 4, wherein during characterization of the DUT 2 the plurality of sampling units 4 are static with respect to the DUT 2 and the dome 5, and spatially distributed over the dome 5 in a far-field range of the DUT 2. The plurality of sampling units 4 are configured to receive a signal inside the test chamber, and transmit an output signal based on the received signal for further analysis. This may provide an assembly for characterization of a DUT 2 in the absence of any mechanical scanning over specific surfaces, i.e. no moving parts, obviating the need for a rotating measurement probe or rotating DUT 2. This can significantly reduce the characterization time from e.g. several hours to a matter of seconds, allowing high speed characterization of a DUT 2 with associated low costs.

On a further note, the assembly can be scaled according to the complexity of the characterization of the DUT 2, whereby the exact number of sampling units 4 and the locations thereof on the dome 5 can be reconfigured. In general, for a low characterization complexity, e.g. low aperture, this may involve a fewer number of sampling units 4, and vice versa.

It is also worthy to note that the assembly may also allow for scalar calibration, i.e. normalization of the response of the plurality of sampling units 4, by using e.g. a reference DUT with a-priori known properties, e.g. a pre-determined radiation pattern or a known radiation pattern.

In certain embodiments, the plurality of sampling units 4 are mounted on an inner surface of the dome 5 forming a closed test chamber. In this case, the signal inside the closed test chamber does not have to penetrate e.g. the panels of the dome 5 before being detected by the plurality of sampling units 4. Moreover, the plurality of sampling units 4 may be less susceptible to e.g. spurious signals in the external environment.

In certain embodiments, the dome 5 comprises a radiation-absorbent material forming a closed test chamber, for example to further shield the signal inside the closed test chamber from external interferences. Moreover, this may prevent any reflection of the signal transmitted by the DUT 2, further improving the characterization quality. As exemplary examples, the radiation-absorbent material may comprise iron ball paint, foam, Jaumann layer(s), split-ring resonator, carbon nanotubes and/or silicon carbide, or any other material, assuming the operational principle of the present invention embodiments described herein may be carried out.

The radiation-absorbent material may be applied as a covering layer over at least a part of the dome 5. As an alternative example, the radiation absorbent material may comprise e.g. a plurality of foam blocks stuck to and covering at least a part of the dome 5.

To further improve characterization quality, in an exemplary embodiment, a ‘Faraday cage’-like construction may be envisaged, wherein, for a closed test chamber, the radiation-absorbent material may cover the inner surface of the dome 5, and a metallic material grid, may cover the outer surface of the dome 5.

To elaborate, if the DUT 2 transmits a signal in a certain frequency range, for example a high frequency signal of e.g. 30 GHz, the radiation-absorbent material may absorb and prevent any reflection of signals in that certain frequency range, e.g. the 30 GHz signal. The metallic material grid may further shield the dome 5 from external interference signals at other frequencies.

In certain embodiments, as shown in FIG. 1, the assembly further comprises a support 9 for mounting a DUT 2 inside the dome 5. The support 9 is arranged for mounting the DUT 2 in a desired location or position inside the dome 5. For example, the support 9 may mount the DUT 2 in a central (physical) location of the dome 5, which is equal to the ‘electrical center’ of the DUT 2. As shown in FIG. 1, the support 9 may comprise a rectangular- or square-shaped bracket whereby the DUT 2 can be mounted thereon, to displace the DUT 2 from the optional bottom platform of the test chamber, wherein the bottom platform of the test chamber is indicated by the grid shaded area shown in FIG. 1.

However, it is noted that the support 9, as shown in FIG. 1, presents a non-limiting implementation. In this regard, the support 9 may comprise e.g. a crane or a lift, as to further position and mount the DUT 2 in other locations inside the test chamber, as desired by the user.

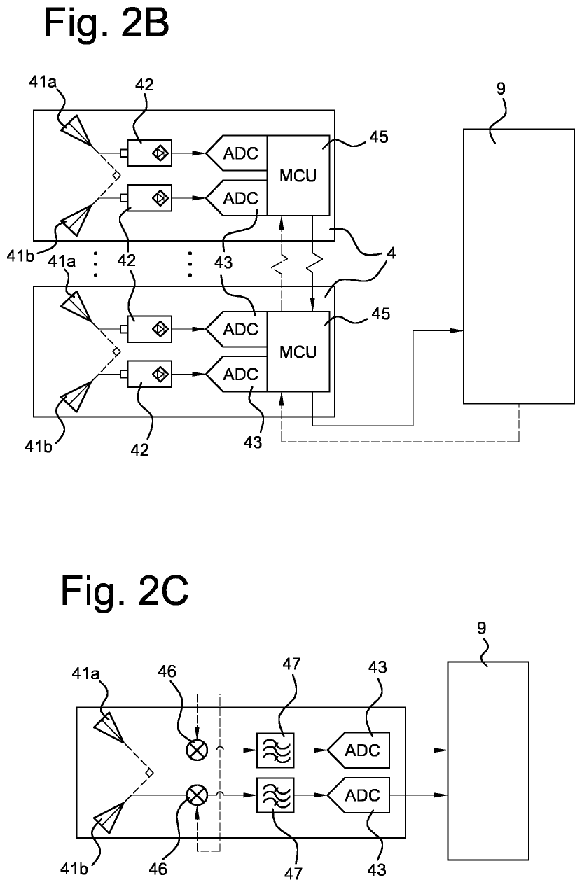

FIGS. 2A-C show schematic diagrams of a part of the assembly, according to three exemplary embodiments of the present invention.

In the exemplary embodiments shown in FIGS. 2A-C, the plurality of sampling units 4 comprises at least one electromagnetic (EM) wave detector 41a, 41b (two in this exemplary embodiment), wherein the at least one electromagnetic wave detector 41a, 41b may comprise an EM antenna. Two EM detectors 41a, 41b are shown in the exemplary embodiments in FIGS. 2A-C, wherein each one of the two EM detectors 41a, 41b is arranged to detect a specific polarization of the received signal, e.g. the polarization as given by the direction of the E-field and H-field vectors of the EM wave.

It is noted that the two EM detectors 41a, 41b, as shown in FIGS. 2A-C, present an exemplary implementation, and, it is possible that only one EM detector may be used to detect the two different polarizations of the EM wave.

To further reduce the characterization time, it may be desirable for the plurality of sampling units 4 to perform further operations, e.g. frequency down-translation and/or signal digitization, once a signal inside the test chamber has been received. To that end, in the exemplary embodiments shown in FIGS. 2A-C, the plurality of sampling units 4 comprises at least one analog-to-digital converter (ADC) 43, wherein the at least one ADC 43 is arranged to convert (and quantize) an analog signal into a digital signal. From this perspective, the at least one ADC 43 may digitize the signal received inside the test chamber, directly at the locations of plurality of sampling units 4, whereby a digital signal is routed out of the plurality of sampling units 4 for further analysis.

Additionally, in order to further improve the performance and functionality of the plurality of sampling units 4, in the exemplary embodiment shown in FIG. 2A, the plurality of sampling units 4 further comprises at least one powermeter 42. The at least one powermeter 42 is arranged to provide a frequency down-translation of a signal. The at least one powermeter 42 comprises a diode, which translates the signal received inside the test chamber, e.g. a radio frequency input signal of 30 GHZ, into a DC voltage signal, wherein the amplitude of the DC voltage is dependent on the root-mean-squared (RMS) of the input signal. In other wording, the at least one powermeter 42 measures the average power of the signal received from inside the test chamber.

Thereafter, the output of the at least one powermeter 42, i.e. the DC output voltage signal, may then be forwarded to the at least one ADC 43. Since the DC output voltage signal has no oscillations or variations, i.e. it has a frequency of (almost) 0 Hz, the at least one ADC 43 may advantageously perform digital quantization comfortably.

As known to the skilled person, owing to Nyquist's law, the at least one ADC 43 will sample at a rate that is (at least) twice the highest frequency at which the at least one ADC 43 wishes to record. Since the DC output voltage signal has a frequency of (almost) 0 Hz, the at least one ADC 43 has a very low sample rate, allowing comfortable and precise digital quantization.

By presence of the at least one powermeter 42, a need for the at least one ADC 43 to have high sampling rate is obviated. To elaborate with an exemplary example, in the absence of at least one powermeter 42, if the frequency of the signal received inside the test chamber is 30 GHz, then, according to Nyquist's law, the at least one ADC 43 has a sampling rate of at least GHz. The skilled person would appreciate the complexity of such instrumentation, and would also appreciate that a sampling rate of 60 GHz may not even be sufficient.

In this context, by directly performing, by the plurality of sampling units 4, frequency down-translation and/or digital quantization upon receiving the signal inside the test chamber, a distributed acquisition unit is realized. This allows the signal inside the test chamber to be directly processed as soon as possible after being received by the plurality of sampling units 4. This obviates a need for an external stimulus acquisition unit, and, moreover, reduce any need for synchronization between a high frequency signal of the DUT 2 and an external stimulus acquisition unit. Subsequently, this further simplifies the characterization of the DUT 2, and subsequently reducing the characterization time thereof.

In the exemplary embodiment shown in FIG. 2A, the plurality of sampling units 4 further comprises a logic gate 44, wherein the logic gate 44 receives a signal from the at least one ADC 43.

The logic gate 44 may be configured to route and transmit the output signal of the plurality of sampling units 4 as desired, thereby controlling the flow of the signal received inside the test chamber for further analysis. In this respect, in certain embodiments, the plurality of sampling units 4 may transmit to, and receive signals from, one another, as illustrated by the dotted and solid lines between the plurality of sampling units 4 in FIG. 2A.

In order to further improve the functionality of the assembly, a further advantageous embodiment (as shown in FIGS. 2A-C) is provided, wherein the assembly further comprises a processing unit 9 connected to the plurality of sampling units 4, and configured to determine at least one characterization parameter of a DUT 2 based on the output signals. In this regard, the processing unit 9 receives the output signal from each of the plurality of sampling units 4, and processes and analyses the output signal so as to determine at least one characterization parameter of the DUT 2. The processing unit 9 may also send a request (as represented by the dashed line from the processing unit 9 to the sampling unit 4 in FIG. 2), and selectively choose which one of the plurality of sampling units 4 to receive the output signal from. For example, if each one of the plurality of sampling units 4 comprises at least one ADC 43 (as described herein), the processing unit 9 may directly store the sampled (ADC) values of the (digitized) output signal.

As non-limiting examples, assuming the DUT 2 comprises an antenna, the characterization parameters may be related to the gain, bandwidth, radiation pattern, beam width, impedance etc. of an antenna.

The processing unit 9 may comprise e.g. a microcontroller, a power supply unit, further digitization instrumentation, a computer with related software, and/or any other equipment to determine at least one characterization parameter of a DUT 2.

FIG. 2B shows a schematic diagram of a part of the assembly, according to a further exemplary embodiment of the present invention. Elements with the same function as in the exemplary embodiment shown in FIG. 2A are indicated by the same reference numerals. In this further exemplary embodiment, the plurality of sampling units 4 further comprises a microcontroller (MCU) 45. The MCU 45 receives the (digitized) signal from the at least one ADC 43, and is arranged to perform simple functions on the signal, e.g. store calibration data, calculate the minimum and maximum voltage of the signal. In addition, the MCU 45 may also directly store the sampled (ADC) values of the (digitized) signal from the at least one ADC 43, and transmit the sampled (ADC) values to e.g. a processing unit 9 for further analysis.

In this respect, since simple functions are performed by the MCU 45, this further reduces the further processing of the received signal at e.g. an external stimulus acquisition unit.

For the exemplary embodiment in FIG. 2B, it has been described that the at least one ADC 43 and MCU 45 are separate features in the plurality of sampling units 4. However, it is worthy to note that the at least one ADC 43 and MCU 45 may be combined into a single feature i.e. single unit or component in the plurality of sampling units 4. For example, the MCU 45 may have at least one ADC 43 embedded within the same chip.

FIG. 2C shows a schematic diagram of a part of the assembly, according to an even further exemplary embodiment of the present invention. Elements with the same function as in the exemplary embodiment shown in FIGS. 2A-B are indicated by the same reference numerals. In this embodiment, the plurality of sampling units 4 further comprises at least one mixer 46 and at least one filter 47.

The at least one mixer 46 is arranged to perform (radio frequency) signal multiplication, wherein signals are mixed together and new signal frequencies are generated. In relation to the present invention, the at least one mixer 46 may receive, i.e. be driven with, a pump signal from an external source, e.g. processing unit 9 (as shown by a dashed line in FIG. 2C), and mix the pump signal with the input (RF) signal received inside the test chamber, wherein the pump signal is of a lower or higher frequency.

As a result, once the pump signal and input (RF) signal are mixed, this enables frequency translation, whereby the input signal is to be converted to a lower (intermediate) frequency. In other wording, frequency down-translation can be performed by the at least one mixer 46, whereby both the amplitude and phase information of the input (RF) signal is retained.

As known to the skilled person, the at least one mixer 46 may have more than one output signal comprising various signal components, including undesired signal content. To that end, the at least one filter 47 may be arranged to filter the undesired content.

As an non-limiting example, the at least one mixer 46 may have two output signals, which are the sum of and difference between the frequencies of the original signals. In this respect, the at least one filter 47 may filter the undesired (higher) frequency content, i.e. reject the output signal of the at least one mixer 46 which is the sum of the pump and input signal frequencies.

In general, the at least one filter 47 may comprise a band-pass filter, but it may also comprise any other filter e.g. low-pass, high-pass, assuming the undesired frequency content is rejected. The filtered signal may then be received by the at least one ADC 43 as to digitize the filtered signal into a digital signal, and output the digitized signal to e.g. a processing unit 9 (as shown by the solid line from the at least one ADC 43 to the processing unit 9 in FIG. 2C), for further analysis.

In this respect, the embodiment as shown in FIG. 2C presents an alternative approach to directly perform frequency down-translation and/or digital quantization. In addition, this embodiment can be combined with the embodiment described herein relating to the processing unit 9 to allow signal quality evaluation, e.g. error-vector magnitude (EVM) measurements, to be performed by the processing unit 9, as to assess the quality of the signal received inside the test chamber. For example, other spurious signals from the external environment, e.g. noise or distortion, may degrade the quality of the signal, and, thus, a measure of the degradation would be desirable.

To elaborate, as known to the skilled person, the final IQ digital downconversion of the received signal is performed in the processing unit 9, as to translate the amplitude and phase data of the received signal into a Cartesian coordinate system (I/O). The vector between the ideal constellation point (i.e. knowledge of the transmitted signal) and the received point in the IQ represents the error vector, whereby the RMS average amplitude of the error vector is the error-vector magnitude (EVM). Thus, in alternative wording, the EVM is a measure of how far the received points are from the ideal locations.

In certain embodiments, the assembly further comprises a jammer device arranged in the dome 5. The jammer device may comprise e.g. a transmitter, portable/stationary jammer, another DUT or an antenna. The jammer device is configured to radiate a jamming signal so as to e.g. replicate spurious signals from the external environment. This is performed so as to test the effect of the assembly in characterizing a DUT 2, and, thus, the quality of the signal transmitted therein, under the presence of a jamming signal. This would provide further information on how a DUT 2 would perform in an external environment with spurious signals. The jammer device may be positioned in any desired location or position inside the test chamber.

Correspondingly, in certain embodiments, at least one of the plurality of sampling units 4 is further configured to transmit a jamming signal. From this perspective, at least one of the plurality of sampling units 4 is configured to radiate the jamming signal. It is noted that the jamming signal may be transmitted, by at least one of the plurality of sampling units 4, in any desired location or position on the dome 5.

It is observed that any of the sampling units disclosed herein, such as the ones shown in FIGS. 2A-C, may also be provided as a separate device, and may be of use in any application domain, including antenna testing, even without making use of the dome assembly disclosed herein.

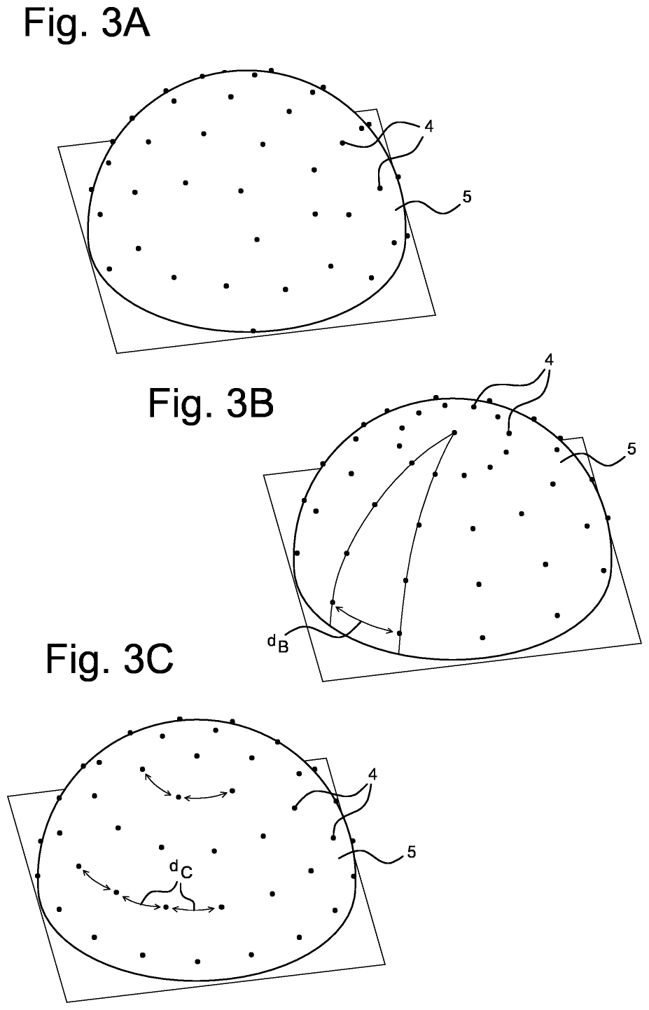

FIGS. 3A-C show a schematic view of the plurality of sampling units 4 spatially distributed over the dome 5, according to three ‘pattern’ embodiments of the present invention, wherein the plurality of sampling units 4 are spatially distributed over the dome 5 in a random pattern or regular pattern, wherein the regular pattern comprises e.g. a linear or function-described pattern.

In the embodiment shown in FIG. 3A, the plurality of sampling units 4 are spatially distributed on of the dome 5 in a random pattern. For example, the plurality of sampling units 4 may have a random distribution based on a Fibonacci sequence, wherein the spacing between any two neighboring sampling units 4 is, thus, random or pseudorandom.

In the embodiment shown in FIG. 3B, the plurality of sampling units 4 are spatially distributed over the dome 5 in a pattern characterized by a distance dB, wherein the distance dB represents equal azimuth spacing between two neighboring sampling units 4.

In the embodiment shown in FIG. 3C, the plurality of sampling units 4 are shown to be spatially distributed over the dome 5 in a pattern characterized by a distance do, wherein the distance do represents fixed spacing between two neighboring sampling units 4.

All in all, the exemplary embodiments shown in FIGS. 3A-C provide an overall good mapping of the plurality of sampling units 4 over the dome 5, wherein e.g. a radiation pattern of a DUT 2 can be determined with good spatial coverage.

From this standpoint, it is noted that the exemplary embodiments shown in FIGS. 3B-C are non-limiting implementations of a regular pattern, and that any type of regular pattern may be used, assuming the operational principle of the present invention embodiments described herein may be carried out. For example, the plurality of sampling units 4 may be spatially distributed over the dome 5 along a single arc, i.e. an individual line, with linear spacing in-between.

In certain embodiments, the plurality of sampling units 4 are spatially distributed over the dome 5 in a user-defined pattern. As described herein, the plurality of sampling units 4 are physical elements which may be attached and unattached to different locations on the dome 5. Thus, as according to the specific characterization of a DUT 2, the plurality of sampling units 4 may be positioned on any location on the dome 5 as desired from a user's perspective. This provides more freedom for the user to perform specific testing procedures, providing additional information about a DUT 2, and, thus, further high quality characterization of a DUT 2.

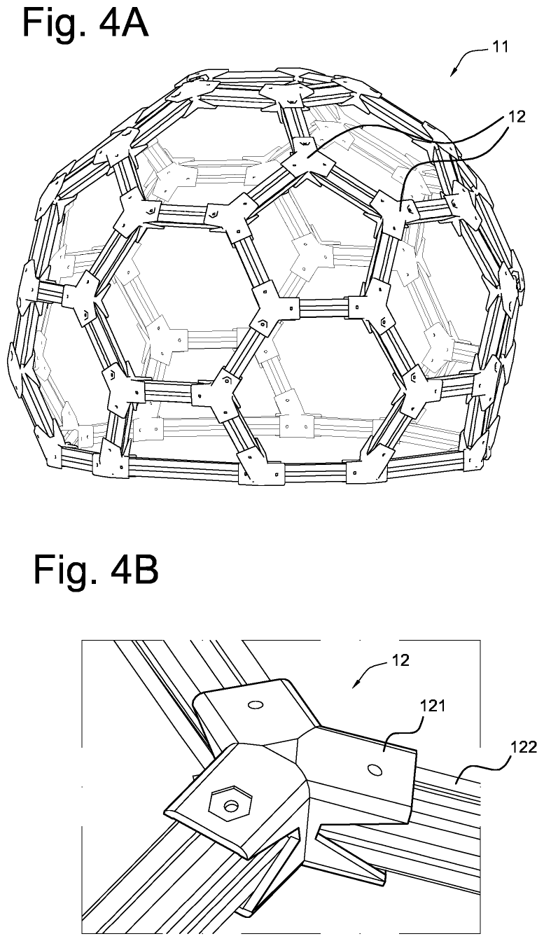

FIGS. 4A-B show a schematic view of the dome 5, according to further embodiments of the present invention.

In the embodiment shown in FIG. 4A, the dome 5 comprises a honeycomb structure 11. Alternatively stated, the dome 5 has a physical skeleton that forms a structural honeycomb framework. This allows for simple and easy construction of e.g. a hemispherical dome 5, yet provide a strong, constructional (physical) framework.

In the embodiment shown in FIG. 4A, the dome 5 comprises a plurality of modular elements 12. In other wording, the dome 5 may be constructed from a plurality of modular elements 12, whereby the plurality of modular elements 12 can be thought of as components that can be put together to construct the (structural framework of the) dome 5, wherein the modular elements 12 may, for example, be attached to, inserted within, screwed into and/or foldable with one another.

This embodiment allows the dome 5 to be easily put away for storage when it is not in use, and also allows for easy transportation of the dome 5. Further, this also allows the (diameter) size of the dome 5 to be easily scaled accordingly; for example, a smaller sized dome 5 may involve a fewer number of modular elements 12, and vice versa. Even further, this also allows the geometry of the dome 5, e.g. a hemispherical dome, to be constructed as desired.

FIG. 4B shows an exemplary embodiment of one of the plurality of modular elements 12, wherein each one of the plurality of modular elements 12 may form a part of the honeycomb structure 11 of the dome 5, as shown in FIG. 4A.

In the exemplary embodiment shown in FIG. 4B, each one of the plurality of modular elements 12 comprises a vertex section 121 and vertex connecting elements 122, wherein the vertex connecting elements 122 are arranged to connect one vertex section 121 to other respective vertex section(s) 121, as to form the structural framework, e.g. the honeycomb structure 11, of the dome 5. As exemplary examples, the vertex section 121 may comprise 3D printing plastic parts, and the vertex connecting elements 122 may comprise aluminum beams.

In certain embodiments, the vertex section 121 and vertex connecting elements 122 may be separate, physical components, wherein the vertex connecting elements 122 may, for example, be inserted or screwed to the vertex section 121. In other embodiments, the vertex section 121 and vertex connecting elements 122 may form a single structure, i.e. they are not separate physical components, wherein the vertex connecting elements 122, may, for example, be inserted or withdrawn from the vertex section 121 in a sliding or screwed manner.

It is noted that FIGS. 4A-B present non-limiting implementations and examples of the present invention, and that further structures of the dome 5 and/or the plurality of modular elements 12 can be envisaged. For example, the dome 5 may comprise an ‘igloo’-like structure, where, in this respect, the plurality of modular elements 12 may e.g. form rectangular blocks of the ‘igloo’-like structure of the dome 5. In another alternative example, the dome 5 may comprise a triangular structure, as constructed from the plurality of modular elements 12, that also provides a strong, constructional framework.

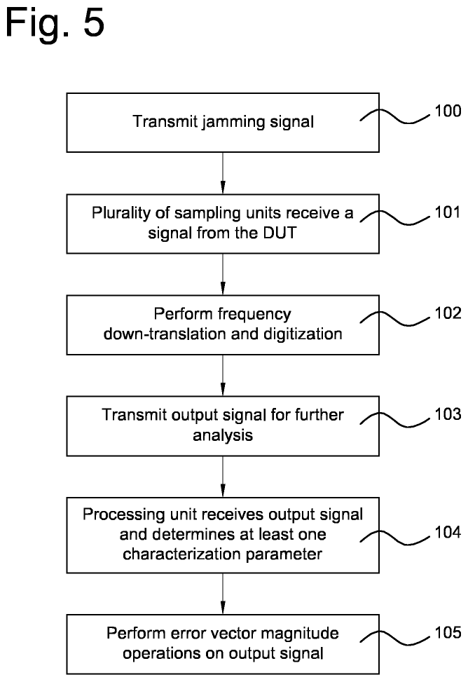

In a further aspect, the present invention relates to a method for characterizing a DUT 2. With reference to FIG. 5 and the embodiments described herein, the method comprises a first step, receiving 101, by a plurality of sampling units 4 static with respect to the DUT 2 and a dome forming a test chamber during characterization of the DUT 2, wherein the plurality of sampling units 4 are spatially distributed over the dome 5 in a far-field range of the DUT 2, a signal from the DUT 2. In this first step, the plurality of sampling units 4 receive the signal, e.g. a propagating, over-the-air (OTA) or wireless signal, from a DUT 2 placed within the test chamber. The plurality of sampling units 4 may be statically mounted on the dome 5, and are not displaced from their respective positions for e.g. the specific duration of time to characterize the DUT 2.

Thereafter, a further step of the method involves transmitting 103, by the plurality of sampling units 4, an output signal based on the received signal for further analysis. In other wording, the plurality of sampling units 4 receive, and locally sample the signal from the DUT 2, and send an output signal for further analysis as to obtain characterization information about the DUT 2.

As a result, the method, as described herein, obviates the need for any mechanical scanning of the DUT 2, or a reference probe antenna, over a large number of surfaces. Consequently, the time for characterization of a DUT 2 is significantly reduced, allowing high speed characterization with associated low costs.

In an advantageous embodiment relating to the method of the present invention, a further step comprises performing, by the plurality of sampling units 4, frequency down-translation and digitization on the signal 102 received from the DUT 2. This method step is performed before the plurality of sampling units 4 transmits an output signal based on the received signal for further analysis. To elaborate, this method step provides a frequency translation of the signal, e.g. a RF signal, received from the DUT 2, to a lower frequency, and direct digitization of the signal into a digital signal.

This allows the plurality of sampling units 4 to transmit an output signal in a form of digitized signal with a lower frequency, further reducing the time for characterization of the DUT 2. The frequency down-translation and digitization by the plurality of sampling units 4 may be performed by elements in the embodiments described above in FIGS. 2A-C.

As an additional step, in certain embodiments, the method further comprises receiving 104, by a processing unit 9, the output signal from the plurality of sampling units 4 and determining, by the processing unit 9, at least one characterization parameter of the DUT 2. The processing unit 9 may receive the signal from each of the plurality of sampling units 4, and analyze such a signal to determine at least one characterization parameter of a DUT 2.

In certain embodiments of the method, a further step is provided, comprising performing error vector magnitude (EVM) measurements 105 by the processing unit 9. This allows the method to evaluate the quality of the signal as received by the processing unit 9, as described above.

To further improve the method for characterizing a DUT 2, an even further step may be included, comprising transmitting a jamming signal 100 by a jammer device mounted inside the dome 5 and/or by at least one of the plurality of sampling units 4. The jammer device and/or at least one of the plurality of sampling units 4 may transmit the signal from any location in the dome 5. The jamming signal may comprise any signal that can interfere with the signal transmitted from a DUT 2, as to test the DUT 2 under the presence of a jamming signal.

As shown in the flow chart of FIG. 5, the jamming signal is transmitted before the plurality of sampling units 4 receive a signal from the DUT 2. It is noted that this presents an exemplary example, and the jamming signal may be transmitted between or during any method step as described herein. As a non-limiting example, the jamming signal may be transmitted during the method step when the plurality of sampling units 4 receive a signal from the DUT 2.

In the above, exemplary embodiments of the present invention have been described with reference to the drawings, which may also be described by the following numbered and interrelated embodiments.

Embodiment 1. An assembly for characterizing a device under test, DUT (2), the assembly comprising a dome (5) forming a test chamber, and a plurality of sampling units (4), wherein during a characterization of the DUT (2) the plurality of sampling units (4) are static with respect to the DUT (2) and the dome (5), and spatially distributed over the dome (5) in a far-field range of the DUT (2), and configured to receive a signal inside the test chamber, and transmit an output signal based on the received signal for further analysis.

Embodiment 2. The assembly according to embodiment 1, wherein the plurality of sampling units (4) comprises at least one analog-to-digital converter (43).

Embodiment 3. The assembly according to embodiment 1 or 2, wherein the plurality of sampling units (4) comprises at least one electromagnetic wave detector (41a, 41b).

Embodiment 4. The assembly according to embodiment 2, wherein the plurality of sampling units (4) further comprises at least one powermeter (42).

Embodiment 5. The assembly according to embodiment 2, wherein the plurality of sampling units (4) further comprises at least one mixer (46) and at least one filter (47).

Embodiment 6. The assembly according to any one of embodiments 1 to 5, wherein the dome (5) forms an open or closed test chamber.

Embodiment 7. The assembly according to embodiment 6, wherein the dome (5) comprises a radiation-absorbent material forming a closed test chamber.

Embodiment 8. The assembly according to any one of embodiments 6 or 7, wherein the plurality of sampling units (4) are mounted on an inner surface of the dome (5) forming a closed test chamber.

Embodiment 9. The assembly according to any one of embodiments 1 to 8, further comprising a jammer device arranged in the dome (5).

Embodiment 10. The assembly according to embodiment 9, wherein at least one of the plurality of sampling units (4) is further configured to transmit a jamming signal.

Embodiment 11. The assembly according to any one of embodiments 1 to 10, further comprising a support (9) for mounting a DUT (2) inside the dome (5).

Embodiment 12. The assembly according to any one of embodiments 1 to 11, wherein the plurality of sampling units (4) are spatially distributed over the dome (5) in a user-defined pattern.

Embodiment 13. The assembly according to any one of embodiments 1 to 11, wherein the plurality of sampling units (4) are spatially distributed over the dome (5) in a random pattern or a regular pattern.

Embodiment 14. The assembly according to any one of embodiments 1 to 13, further comprising a processing unit (9) connected to the plurality of sampling units (4), and configured to determine at least one characterization parameter of a DUT (2) based on the output signals.

Embodiment 15. The assembly according to any one of embodiments 1 to 14, wherein the dome (5) comprises a plurality of modular elements (12).

Embodiment 16. A method for characterizing a device under test, DUT, (2), the method comprising: Receiving (101), by a plurality of sampling units (4) static with respect to the DUT (2) and a dome (5) forming a test chamber during characterization of the DUT (2), wherein the plurality of sampling units (4) are spatially distributed over the dome (5) in a far-field range of the DUT (2), a signal from the DUT (2), and transmitting (103), by the plurality of sampling units (4), an output signal based on the received signal for further analysis.

Embodiment 17. The method according to embodiment 16, further comprising performing, by the plurality of sampling units (4), frequency down-translation and digitization on the signal (102) received from the DUT (2).

Embodiment 18. The method according to embodiment 16 or 17, further comprising receiving (104), by a processing unit (9), the output signal from the plurality of sampling units (4) and determining (104), by the processing unit (9), at least one characterization parameter of the DUT (2).

Embodiment 19. The method according to embodiment 18, further comprising performing, by the processing unit (9), error vector magnitude measurements (105).

Embodiment 20. The method according to any one of embodiments 16 to 19, further comprising transmitting (100), by a jammer device mounted inside the dome (5) and/or by at least one of the plurality of sampling units (4), a jamming signal.

The present invention has been described above with reference to a number of exemplary embodiments as shown in the drawings. Modifications and alternative implementations of some parts or elements are possible, and are included in the scope of protection as defined in the appended claims.

The examples and embodiments described herein serve to illustrate rather than limit the invention. Reference signs placed in parentheses in the claims shall not be interpreted to limit the scope of the claims. The person skilled in the art will be able to design alternative embodiments without departing from the spirit and scope of the present disclosure, as defined by the appended claims and their equivalents.

1. An assembly for characterizing a device under test, DUT, the assembly comprising a dome forming a shielded test chamber, and a user variable and reconfigurable plurality of directional dually polarized sampling units, wherein during a characterization of the DUT the plurality of directional dually polarized sampling units are static with respect to the DUT and the dome, and spatially distributed over the dome in a far-field range of the DUT, and configured to receive a signal inside the shielded test chamber, and transmit an output signal based on the received signal for further analysis.

2. The assembly according to claim 1, wherein the plurality of directional dually polarized sampling units comprises at least one analog-to-digital converter.

3. The assembly according to claim 1, wherein the plurality of directional dually polarized sampling units comprises at least one electromagnetic wave detector.

4. The assembly according to claim 2, wherein the plurality of directional dually polarized sampling units further comprises at least one powermeter.

5. The assembly according to claim 2, wherein the plurality of directional dually polarized sampling units further comprises at least one mixer and at least one filter.

6. The assembly according to claim 1, wherein the dome forms a closed test chamber.

7. The assembly according to claim 1, wherein the dome comprises a radiation-absorbent material forming a shielded test chamber.

8. The assembly according to claim 6, wherein the plurality of directional dually polarized sampling units are mounted on an inner surface of the dome forming the shielded test chamber.

9. The assembly according to claim 1, further comprising a jammer device arranged in the dome.

10. The assembly according to claim 9, wherein at least one of the plurality of directional dually polarized sampling units is further configured to transmit a jamming signal.

11. The assembly according to claim 1, further comprising a support for mounting a DUT inside the dome.

12. The assembly according to claim 1, wherein the plurality of directional dually polarized sampling units are spatially distributed over the dome in a user-defined pattern.

13. The assembly according to claim 1, wherein the plurality of directional dually polarized sampling units are spatially distributed over the dome in a random pattern or a regular pattern.

14. The assembly according to claim 1, further comprising a processing unit connected to the plurality of directional dually polarized sampling units, and configured to determine at least one characterization parameter of a DUT based on the output signals.

15. The assembly according to claim 1, wherein the dome comprises a plurality of modular elements.

16. The assembly according to claim 1, wherein the plurality of directional dually polarized sampling units are separate physical elements of the assembly and are configured to be attached and detached from the dome.

17. A method for characterizing a device under test, DUT, the method comprising: receiving, by a user variable and reconfigurable plurality of directional dually polarized sampling units static with respect to the DUT and a dome forming a shielded test chamber during characterization of the DUT, wherein the plurality of directional dually polarized sampling units are spatially distributed over the dome in a far-field range of the DUT, a signal from the DUT, and
transmitting by the plurality of directional dually polarized sampling units, an output signal based on the received signal for further analysis.

18. The method according to claim 17, further comprising performing, by the plurality of directional dually polarized sampling units, frequency down-translation and digitization on the signal received from the DUT.

19. The method according to claim 17, further comprising receiving, by a processing unit, the output signal from the plurality of directional dually polarized sampling units and determining, by the processing unit, at least one characterization parameter of the DUT.

20. The method according to claim 19, further comprising performing, by the processing unit, error vector magnitude measurements.

21. The method according to claim 17, further comprising transmitting, by a jammer device mounted inside the dome and/or by at least one of the plurality of directional dually polarized sampling units, a jamming signal.

22. The method according to claim 17, wherein the plurality of directional dually polarized sampling units are separate physical elements of the assembly and are configured to be attached and detached from the dome.
